(19) United States
(12) Patent Application Publication
(10) Pub. No.: US 2015/0380531 A1
(43) Pub. Date: Dec. 31, 2015

(54) HETEROJUNCTION BIPOLAR TRANSISTOR WITH IMPROVED CURRENT GAIN

(71) Applicant: WIN SEMICONDUCTOR CORP., Kuei Shan Hsiang (TW)

(72) Inventors: H. P. XIAO, Kuei Shan Hsiang (TW); Galen HSIEH, Kuei Shan Hsiang (TW)

(21) Appl. No.: 14/847,743

(22) Filed: Sep. 8, 2015

Related U.S. Application Data
(63) Continuation-in-part of application No. 13/530,956, filed on Jun. 22, 2012.

(51) Int. Cl. H01L 29/737; H01L 29/205

(52) U.S. Cl. CPC H01L 29/7371; H01L 29/205

(57) ABSTRACT

A heterojunction bipolar transistor (HBT) with improved current gain, in which the HBT comprises a substrate, a modulation-doped buffer structure, an n-type sub-collector layer, an n-type collector layer, a p-type base layer, an n-type emitter layer, an emitter cap layer, and an emitter contact layer, a collector electrode, a base electrode and an emitter electrode, wherein the modulation-doped buffer structure includes at least one doped layer having a thickness of at least 10 Å and less than 3000 Å and doped a dopant element with doping concentration at least 3×10¹⁷cm⁻³ and no greater than 2×10²⁰ cm⁻³, wherein the dopant element is selected from the group consisting of C, Zn, Mg, Be and S.

The present invention is a continuation in part (CIP) to a U.S. patent application Ser. No. 13/530,956 filed on Jun. 22, 2012.

### FIELD OF THE INVENTION

The present invention relates to a heterojunction bipolar transistor (HBT), and in particular, to an HBT with improved current gain by having a modulation-doped buffer structure inserted between the n-type sub-collector layer and the substrate layer.

### BACKGROUND OF THE INVENTION

An HBT with improved current gain properties has the advantage of high efficiency, high linearity, high power density, and small device size. It is an important device commonly used as a microwave power amplifier in wireless communications.

FIG. 1 is a schematic showing the cross-sectional view of the epitaxial layer structure for a conventional HBT. The epitaxial layers are formed on a substrate 101, comprising sequentially an n-type sub-collector layer 107, an n-type collector layer 109, a p-type base layer 111, an n-type emitter layer 113, an emitter cap layer 115, and an emitter contact layer 117.

After the epitaxial growth of the device layer structure, a base electrode 121, a collector electrode 119, and an emitter electrode 123 are fabricated. A base contact region and a collector contact region are first defined by conventional photolithography followed by etching processes. The etching process for the base contact region is terminated at the base layer 111, while the etching process for the collector contact region is terminated at the sub-collector layer 107. The base electrode 121 is formed in the base contact region, forming an ohmic contact with the base layer 111. In the collector electrode contact region, the collector electrode 119 is formed and forms an ohmic contact with the sub-collector layer 107. The emitter electrode 123 is formed directly on the emitter contact layer 117 and also has an ohmic contact with the emitter contact layer 117.

For the conventional HBT, high current gain properties are not easy to achieve. It is commonly believed that the device current gain properties are sensitive to the crystalline quality of the collector or the sub-collector layer. There are two main factors that would degrade the crystalline quality of the sub-collector layer. The first one is the high dislocation density in the substrate 101, which would propagate into the sub-collector thereon during epitaxial growth and hence reduce the current gain of the HBT device. The second one is the high doping level in the sub-collector layer. In order to reduce the resistive losses in the collector electrode 119, the sub-collector layer 107 is usually heavily doped (preferably with Si). However, as the doping level is increased, the defect density in the sub-collector layer 107 is also increased, leading to a degraded current gain.

To reduce the dislocation density in the sub-collector layer propagating from the substrate, a method has been disclosed in a prior art. FIG. 2 is a schematic showing the epitaxial layer structure of an HBT with improved current gain in another prior art. The main structure is basically the same as the structure shown in FIG. 1, except that a buffer layer 103 is inserted between the substrate 101 and the sub-collector layer 107. The buffer layer 103 is formed of an oxygen doped AlGaAs layer, which could suppress the dislocations penetrating from the substrate 101 into the sub-collector layer of the HBT, and hence improve the device current gain.

To avoid the degradation in the current gain caused by the heavy doping in the sub-collector layer 107, a method has been disclosed in another prior art. FIG. 3 is a schematic showing the cross-sectional view of a high current gain HBT of another prior art. The main structure is similar to the structure shown in FIG. 1, except that a δ-doped layer 105 is inserted between the substrate 101 and the sub-collector layer 107. The δ-doped layer 105 is a doping layer with a nominal thickness of only one atomic layer (also called planar doping layer). The dopant of the δ-doped layer 105 is usually Si. The defect density in the sub-collector layer 107 generated by the high doping level can be suppressed by using the δ-doped layer. The device current gain can also be improved accordingly.

In order to tackle both of the two aforementioned factors that considerably limit the device current gain, the present invention provides an improved HBT structure, which can suppress not only the dislocations penetrating from the substrate 101 into the sub-collector layer, but also the defect density in the sub-collector layer 107 generated by the high doping level. Therefore, a lower collector resistance and hence an HBT device with improved current gain and long-term reliability can be achieved.

### SUMMARY OF THE INVENTION

The main object of the present invention is to provide an improved HBT, in which a modulation-doped buffer structure is inserted between the substrate and the n-type sub-collector layer of the HBT, wherein the modulation-doped buffer structure includes at least one doped layer having a thickness of at least 10 Å and less than 3000 Å and doped with a dopant element at doping concentration at least 3×10¹⁷ cm⁻³ and no greater than 2×10²° cm⁻³, wherein the dopant element is selected from the group consisting of C, Zn, Mg, Be and S. The modulation-doped buffer structure can absorb the defects, probably the Ga vacancies, generated during the epitaxial growth of the n-type sub-collector layer when heavily doped with Si impurities. The modulation-doped buffer structure can also suppress the upward propagation of the dislocations from the substrate. By choosing a suitable material and a dopant for the modulation-doped buffer structure, and optimizing the doping level therein, an improved HBT with demanded device performances can be obtained. Its on-state resistance can be lowered; the efficiency of the power amplifier can be enhanced; and the current gain can be improved.

To reach the objects stated above, the present invention provides a heterojunction bipolar transistor (HBT) with improved current gain, comprising: a substrate; a modulation-doped buffer structure formed on said substrate, wherein said modulation-doped buffer structure includes at least one doped layer having a thickness of at least 10 Å and less than 3000 Å and doped with a dopant element at doping concentration at least 3×10¹⁷ cm⁻³ and no greater than 2×10²⁰ cm⁻³, wherein said dopant element is selected from the group consisting of C, Zn, Mg, Be and S; an n-type sub-collector layer formed on said modulation-doped buffer structure; an n-type collector layer formed on said n-type sub-collector layer; a p-type base layer formed on said n-type collector layer; an n-type emitter layer formed on said p-type base layer; a collector electrode formed at one end of said n-type sub-collector layer; a base electrode formed at one end of said p-type base layer; and an emitter electrode formed on said n-type emitter layer.

In an embodiment, said modulation-doped buffer structure is formed of material selected from the group consisting of GaAs, AlGaAs, InGaP, InAlP, InGaAsP and AlGaInP.

In an embodiment, said modulation-doped buffer structure further comprises at least one additional layer.

In an embodiment, said modulation-doped buffer structure is formed by alternately stacking said at least one doped layer and said at least one additional layer.

In an embodiment, each of said at least one additional layer is fully doped, partially doped or undoped.

In an embodiment, each of said at least one additional layer is fully doped, partially doped or undoped and the doping concentration is at least 3×10¹⁷ cm⁻³ and no greater than 2×10²⁰ cm⁻³ with doped a thickness less than 10 Å.

In an embodiment, each of said at least one additional layer is fully doped, partially doped or undoped and the doping concentration is less than 3×10¹⁷ cm⁻³ or greater than 2×10²⁰ cm⁻³.

In an embodiment, said dopant element is C.

In an embodiment, said dopant element is Zn.

In an embodiment, said dopant element is Mg.

In an embodiment, said dopant element is Be.

In an embodiment, said dopant element is S.

In an embodiment, said substrate is formed of GaAs.

In an embodiment, further comprising an n-type emitter cap layer between said n-type emitter layer and said emitter electrode.

In an embodiment, further comprising an n-type emitter contact layer between said n-type emitter cap layer and said emitter electrode.

In an embodiment, further comprising an n-type emitter contact layer between said n-type emitter layer and said emitter electrode.

In an embodiment, said at least one doped layer has a thickness of at least 30 Å and less than 3000 Å and is doped with said dopant element at doping concentration at least 3×10¹⁷ cm⁻³ and no greater than 2×10²⁰ cm⁻³.

In an embodiment, said at least one doped layer has a thickness of at least 50 Å and less than 3000 Å and is doped with said dopant element at doping concentration at least 3×10¹⁷ cm⁻³ and no greater than 2×10²⁰ cm⁻³.

In an embodiment, said at least one doped layer has a thickness of at least 100 Å and less than 3000 Å and is doped with said dopant element at doping concentration at least 3×10¹⁷ cm³ and no greater than 2×10²⁰ cm³.

In an embodiment, said at least one doped layer has a thickness of at least 200 Å and less than 3000 Å and is doped with said dopant element at doping concentration at least 3×10¹⁷ cm⁻³ and no greater than 2×10²⁰ cm⁻³.

For further understanding the characteristics and effects of the present invention, some preferred embodiments referred to drawings are in detail described as follows.

### BRIEF DESCRIPTION OF DRAWINGS

FIG. 1 is a schematic showing the cross-sectional view of the epitaxial layer structure for a conventional HBT.

FIG. 2 is a schematic showing the cross-sectional view of the epitaxial layer structure of an HBT with improved current gain in another prior art.

FIG. 3 is a schematic showing the cross-sectional view of a high current gain HBT in another prior art.

FIG. 4 is schematic showing the cross-sectional view of the improved HBT of an embodiment provided by the present invention.

FIG. 4A-4K are schematics showing the cross-sectional views of the modulation-doped buffer structure according to the various embodiments provided by the present invention.

FIG. 5-7 are schematics showing the cross-sectional views of the improved HBT according to the various embodiments provided by the present invention.

FIG. 8, 8A, 8B are the performance of the various embodiments of the present invention.

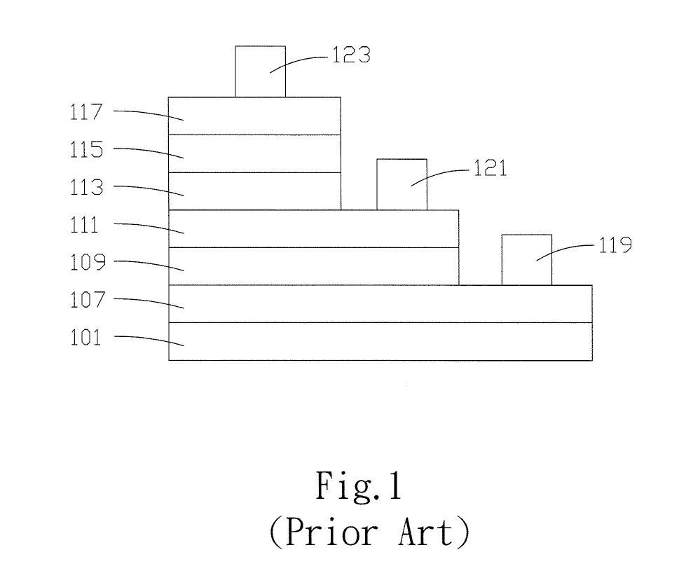

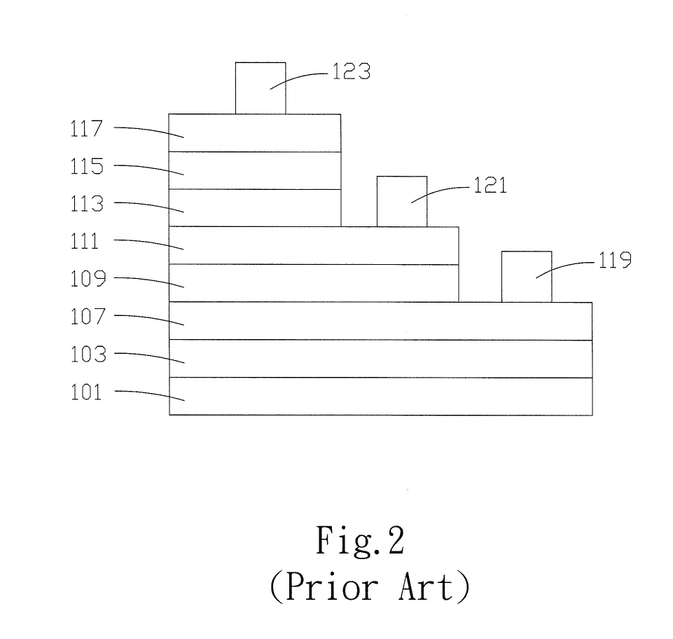

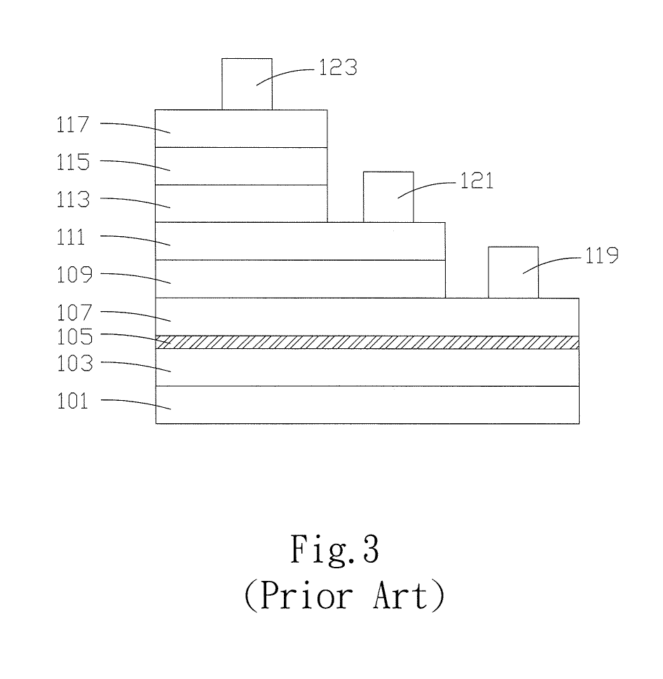

### DETAILED DESCRIPTIONS OF PREFERRED EMBODIMENTS

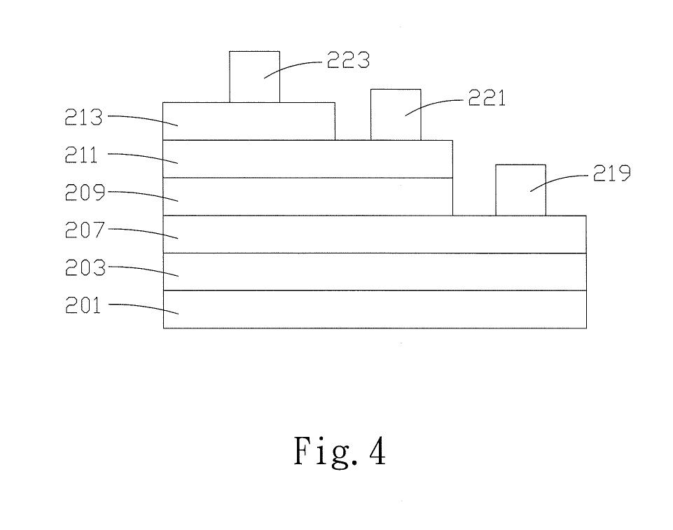

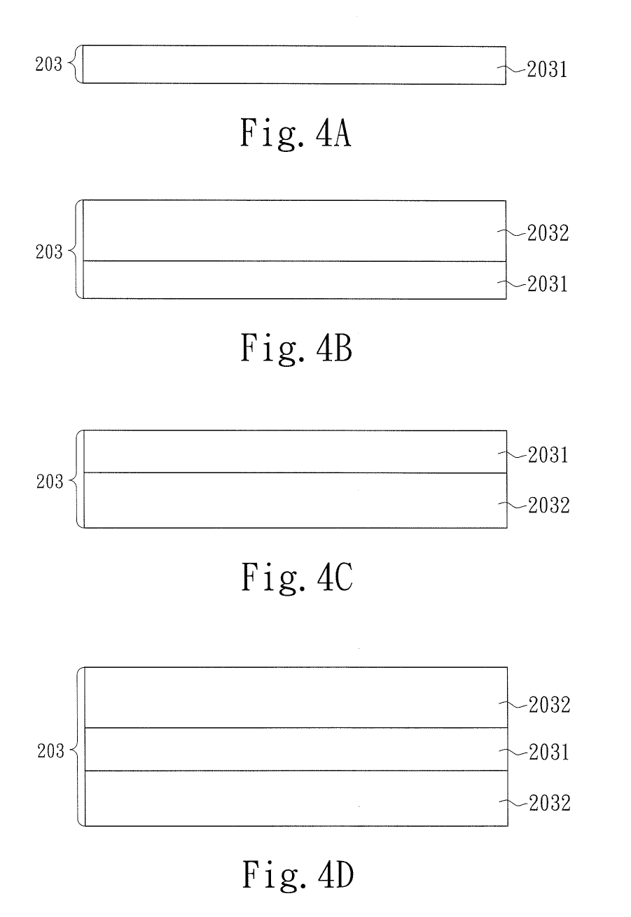

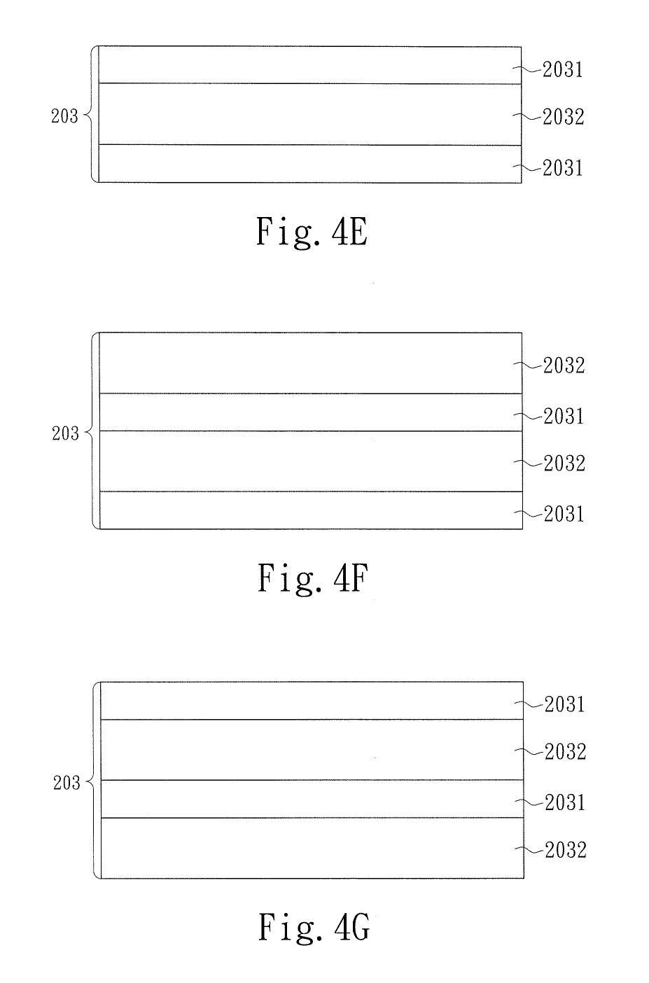

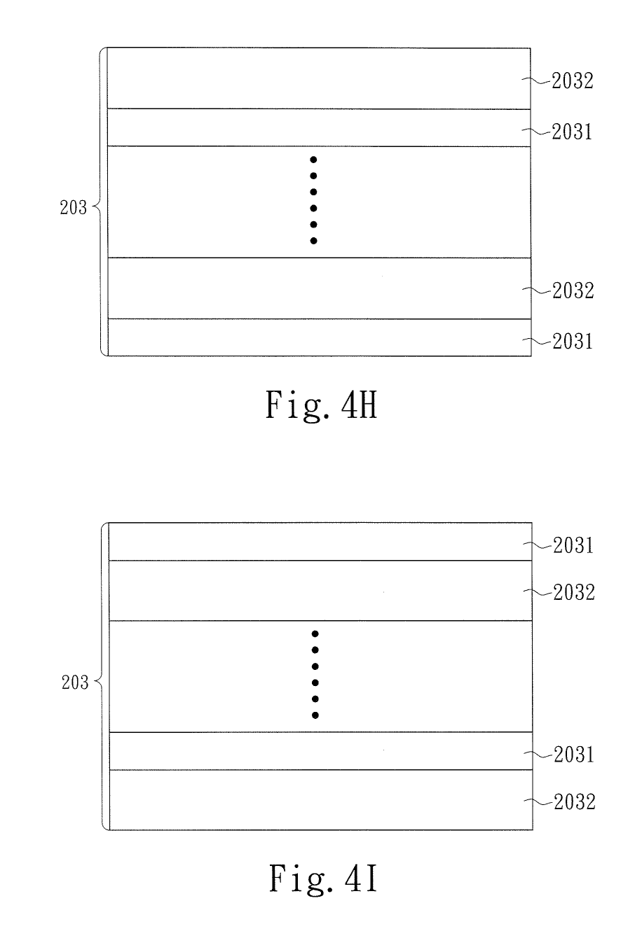

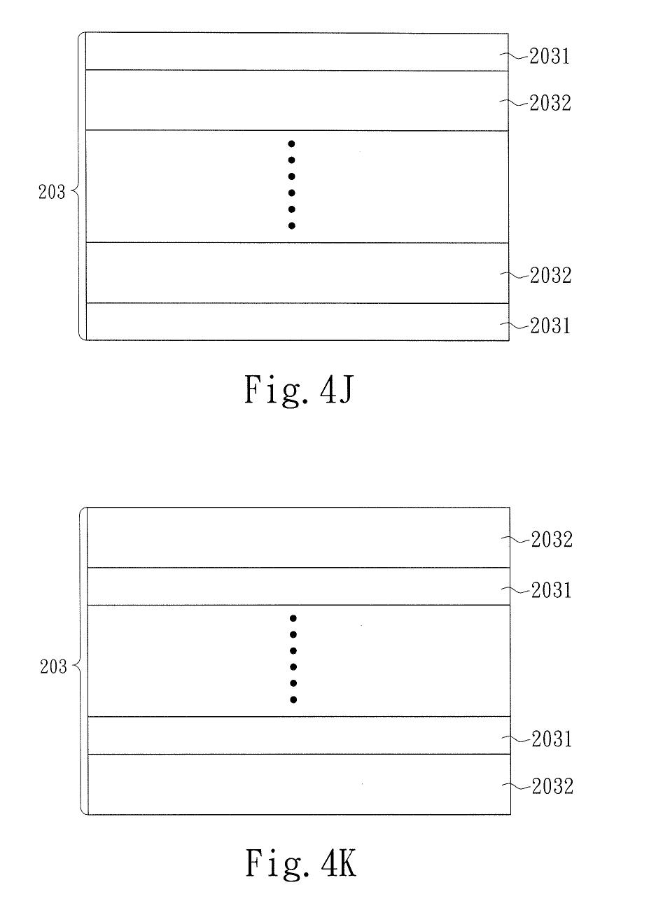

FIG. 4 is a schematic showing the improved HBT provided by the present invention, which comprises: a substrate 201; a modulation-doped buffer structure 203 formed on the substrate 201, wherein the modulation-doped buffer structure 203 includes at least one doped layer 2031 having a thickness of at least 10 Å and less than 3000 Å and doped with a dopant element at doping concentration at least 3×10¹⁷ cm⁻³ and no greater than 2×10²⁰ cm⁻³, wherein the dopant element is selected from the group consisting of C, Zn, Mg, Be and S; an n-type sub-collector layer 207 formed on the modulation-doped buffer structure 203; an n-type collector layer 209 formed on the n-type sub-collector layer 207; a p-type base layer 211 formed on the n-type collector layer 209; an n-type emitter layer 213 formed on the p-type base layer 211; a collector electrode 219 formed at one end of the n-type sub-collector layer 207; a base electrode 221 formed at one end of the p-type base layer 211; and an emitter electrode 223 formed on the n-type emitter layer 213.

In the embodiments provided by the present invention, the substrate 201 is preferably a semi-insulating GaAs substrate. The modulation-doped buffer structure 203 is formed on the substrate 201 by conventional epitaxial growth techniques, such as molecular beam epitaxy (MBE) or metalorganic chemical vapor deposition (MOCVD). The material for the modulation-doped buffer structure 203 is preferably selected from the group consisting of GaAs, AlGaAs, InGaP, InAlP, InGaAsP and AlGaInP. The dopant of the modulation-doped buffer structure 203 is preferably a material selected from the group consisting of C, Zn, Mg, Be, S, and the combination of the above materials. The preferable thickness of the modulation-doped buffer structure 203 is between 10 Å and 10000 Å. After the formation of the modulation-doped buffer structure 203, the n-type sub-collector layer 207 is then grown thereon. The n-type sub-collector layer 207 is usually a layer of n-type GaAs heavily doped with Si. The n-type collector layer 209 is then grown on the n-type sub-collector layer 207. The n-type collector layer 209 is usually a layer of n-type GaAs also doped with Si. The p-type base layer 211 is then grown on the n-type collector layer 209. The p-type base layer 211 is usually a layer of p-type doped GaAs, and doped preferably with carbon or some other p-type dopants. The epitaxial layer structure is finally completed by growing an n-type emitter layer 213 on the p-type base layer 211. The n-type emitter layer 213 is made preferably of Si-doped n-type InGaP.

In an embodiment, the modulation-doped buffer structure 203 further comprises at least one additional layer 2032.

In another embodiment, the additional layer 2032 may be fully doped, partially doped or undoped.

In one embodiment, a less than 10 Å thickness of the additional layer 2032 may be doped with the dopant element at doping concentration at least 3×10¹⁷ cm⁻³ and no greater than 2×10²⁰ cm⁻³.

In an embodiment, the additional layer 2032 may be doped with the dopant element at doping concentration less than 3×10¹⁷ cm⁻³ or greater than 2×10²⁰ cm⁻³.

In some embodiments, the modulation-doped buffer structure 203 further comprises at least one additional layer 2032 and the modulation-doped buffer structure 203 is formed by alternately stacking the at least one doped layer 2031 and the at least one additional layer 2032, wherein the at least one doped layer 2031 has a thickness of at least 10 Å and less than 3000 Å and is doped with a dopant element at doping concentration at least 3×10¹⁷ cm⁻³ and no greater than 2×10²⁰ cm⁻³, wherein the dopant element is selected from the group consisting of C, Zn, Mg, Be and S.

FIG. 4A-4K are schematics showing the cross-sectional views of the modulation-doped buffer structure according to the various embodiments provided by the present invention. FIG. 4A-4K show various embodiments of the modulation-doped buffer structure 203 formed by alternately stacking the at least one doped layer 2031 and the at least one additional layer 2032.

Please refer to FIG. 4A. The modulation-doped buffer structure 203 comprises one doped layer 2031.

Please refer to FIG. 4B. The modulation-doped buffer structure 203 comprises one doped layer 2031 and one additional layer 2032 formed on the one doped layer 2031.

Please refer to FIG. 4C. The modulation-doped buffer structure 203 comprises one additional layer 2032 and one doped layer 2031 formed on the one additional layer 2032.

Please refer to FIG. 4D. The modulation-doped buffer structure 203 comprises two additional layers 2032 and one doped layer 2031, wherein the one doped layer 2031 is formed between the two additional layers 2032.

Please refer to FIG. 4E. The modulation-doped buffer structure 203 comprises two doped layers 2031 and one additional layer 2032, wherein the one additional layer 2032 is formed between the two doped layers 2031.

Please refer to FIG. 4F. The modulation-doped buffer structure 203 comprises two doped layers 2031 and two additional layers 2032, wherein the two doped layers 2031 and the two additional layers 2032 are alternately stacked, and wherein the bottom of the modulation-doped buffer structure 203 is one of the two doped layers 2031 and the top of the modulation-doped buffer structure 203 is one of the two additional layers 2032.

Please refer to FIG. 4G. The modulation-doped buffer structure 203 comprises two doped layers 2031 and two additional layers 2032, wherein the two doped layers 2031 and the two additional layers 2032 are alternately stacked, and wherein the bottom of the modulation-doped buffer structure 203 is one of the two additional layers 2032 and the top of the modulation-doped buffer structure 203 is one of the two doped layers 2031.

Please refer to FIG. 4H. The modulation-doped buffer structure 203 comprises multiple doped layers 2031 and multiple additional layers 2032, wherein the multiple doped layers 2031 and the multiple additional layers 2032 are alternately stacked, and wherein the bottom of the modulation-doped buffer structure 203 is one of the multiple doped layers 2031 and the top of the modulation-doped buffer structure 203 is one of the multiple additional layers 2032.

Please refer to FIG. 4I. The modulation-doped buffer structure 203 comprises multiple doped layers 2031 and multiple additional layers 2032, wherein the multiple doped layers 2031 and the multiple additional layers 2032 are alternately stacked, and wherein the bottom of the modulation-doped buffer structure 203 is one of the multiple additional layers 2032 and the top of the modulation-doped buffer structure 203 is one of the multiple doped layers 2031.

Please refer to FIG. 4J. The modulation-doped buffer structure 203 comprises multiple doped layers 2031 and multiple additional layers 2032, wherein the multiple doped layers 2031 and the multiple additional layers 2032 are alternately stacked, and wherein the bottom of the modulation-doped buffer structure 203 is one of the multiple doped layers 2031 and the top of the modulation-doped buffer structure 203 is the other one of the multiple doped layers 2031.

Please refer to FIG. 4K. The modulation-doped buffer structure 203 comprises multiple doped layers 2031 and multiple additional layers 2032, wherein the multiple doped layers 2031 and the multiple additional layers 2032 are alternately stacked, and wherein the bottom of the modulation-doped buffer structure 203 is one of the multiple additional layers 2032 and the top of the modulation-doped buffer structure 203 is the other one of the multiple additional layers 2032.

In the embodiments shown in FIG. 4A-4K, every doped layer 2031 has a thickness of at least 10 Å and less than 3000 Å and is doped with a dopant element at doping concentration at least 3×10¹⁷ cm⁻³ and no greater than 2×10²⁰ cm⁻³, wherein the dopant element is selected from the group consisting of C, Zn, Mg, Be and S.

In an embodiment, the doped layer 2031 has a thickness of at least 30 Å and less than 3000 Å and is doped with a dopant element at doping concentration at least 3×10¹⁷ cm⁻³ and no greater than 2×10²⁰ cm⁻³, wherein the dopant element is selected from the group consisting of C, Zn, Mg, Be and S.

In another embodiment, the doped layer 2031 has a thickness of at least 50 Å and less than 3000 Å and is doped with a dopant element at doping concentration at least 3×10¹⁷ cm⁻³ and no greater than 2×10²⁰ cm⁻³, wherein the dopant element is selected from the group consisting of C, Zn, Mg, Be and S.

In an embodiment, the doped layer 2031 has a thickness of at least 100 Å and less than 3000 Å and is doped with a dopant element at doping concentration at least 3×10¹⁷ cm⁻³ and no greater than 2×10²⁰ cm⁻³, wherein the dopant element is selected from the group consisting of C, Zn, Mg, Be and S.

In another embodiment, the doped layer 2031 has a thickness of at least 200 Å and less than 3000 Å and is doped with a dopant element at doping concentration at least 3×10¹⁷ cm⁻³ and no greater than 2×10²⁰ cm⁻³, wherein the dopant element is selected from the group consisting of C, Zn, Mg, Be and S.

In some embodiments, the doped layer 2031 is doped with a dopant element at doping concentration at least 3×10¹⁷ cm⁻³ and no greater than 2×10²⁰ cm⁻³, wherein the dopant element is selected from the group consisting of C, Zn, Mg, Be and S, and wherein the doped layer 2031 has a thickness of at least 20 Å and less than 3000 Å, at least 40 Å and less than 3000 Å, at least 60 Å and less than 3000 Å, at least 80 Å and less than 3000 Å, at least 120 Å and less than 3000 Å, at least 150 Å and less than 3000 Å, at least 180 Å and less than 3000 Å, at least 250 Å and less than 3000 Å, at least 300 Å and less than 3000 Å, at least 350 Å and less than 3000 Å, at least 400 Å and less than 3000 Å, at least 450 Å and less than 3000 Å or at least 500 Å and less than 3000 Å.

In the embodiments shown in FIG. 4A-4K, the additional layer 2032 may be doped, partially doped or undoped. And less than 10 Å thickness of the additional layer 2302 may be doped with a dopant element at doping concentration at least 3×10′⁷ cm⁻³ and no greater than 2×10²⁰ cm⁻³, wherein the dopant element is selected from the group consisting of C, Zn, Mg, Be and S.

In the embodiments shown in FIG. 4A-4K, the additional layer 2032 may be doped, partially doped or undoped. And the additional layer 2302 may be fully or partially doped with a dopant element at doping concentration less than 3×10′⁷ cm⁻³ or greater than 2×10²⁰ cm⁻³, wherein the dopant element is selected from the group consisting of C, Zn, Mg, Be and S.

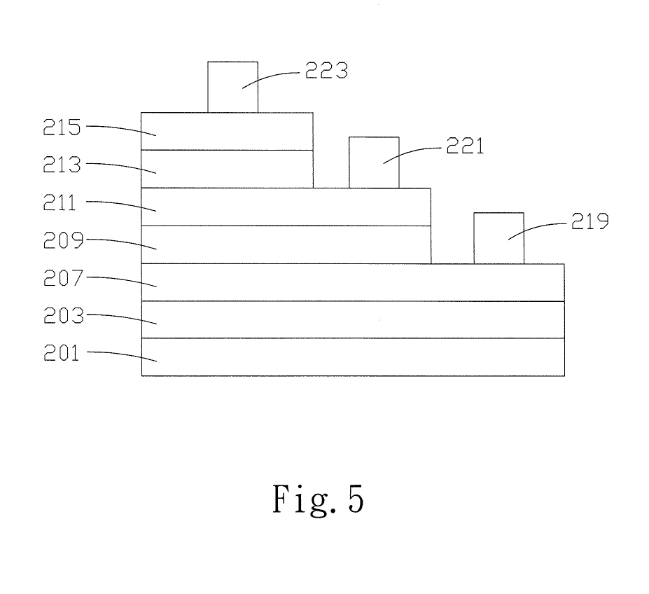

FIG. 5 is a schematic showing the device layer structure of another embodiment of the present invention. The structure is basically the same as the embodiment shown in FIG. 4, except that an emitter cap layer 215 is inserted between the n-type emitter layer 213 and the emitter electrode 223. The emitter cap layer 215 is made preferably of Si-doped n-type GaAs. It can also be an n-type AlGaAs layer, or an n-type multilayer formed by the combinations of GaAs and AlGaAs layers. In addition, the emitter electrode 223 is formed directly on the emitter cap layer 215 and forms an ohmic contact.

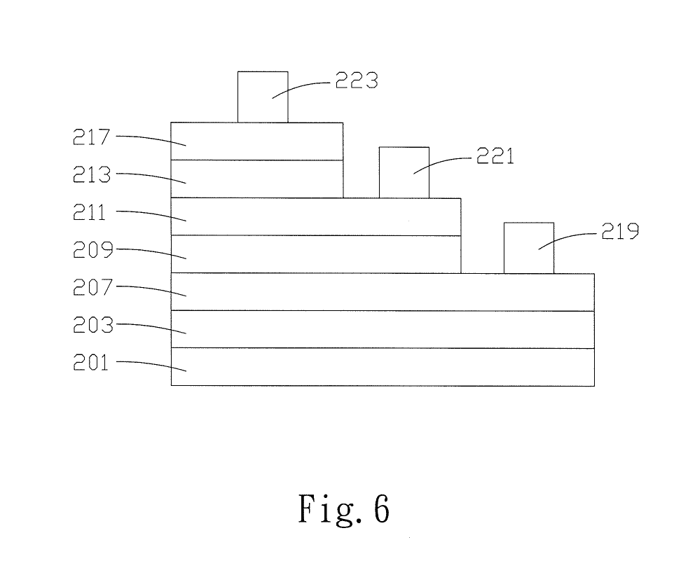

FIG. 6 is a schematic showing the device layer structure of another embodiment of the present invention. The main structure is basically the same as the embodiment shown in FIG. 4, except that an emitter contact layer 217 is inserted between the n-type emitter layer 213 and the emitter electrode 223. The emitter contact layer 217 is preferably a n-type InGaAs layer, and the preferable dopant is Te, Si or similar materials. In this structure, the emitter electrode 223 forms an ohmic contact with the emitter contact layer 217.

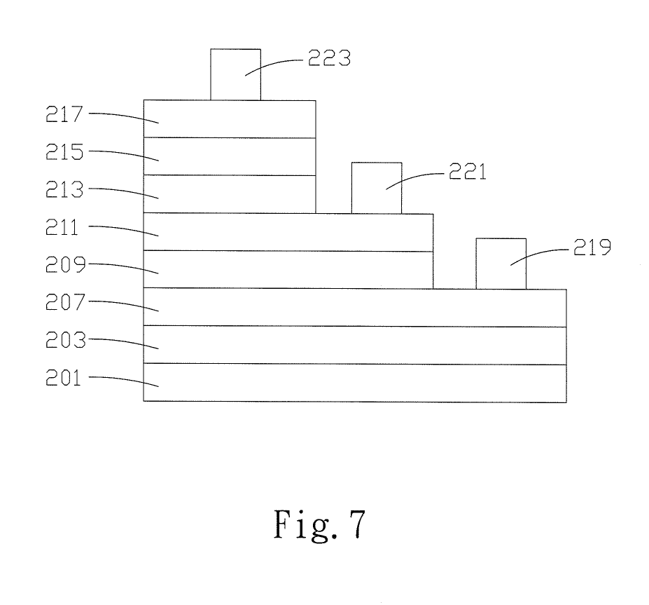

FIG. 7 is a schematic showing the device layer structure of another embodiment of the present invention. The main structure is the same as the embodiment shown in FIG. 6, except that an emitter cap layer 215 is inserted between the n-type emitter layer 213 and the emitter contact layer 217. The emitter cap layer 215 is made preferably of Si-doped n-type GaAs. It can also be an n-type AlGaAs layer, or an n-type multilayer formed by the combinations of GaAs and AIGaAs layers.

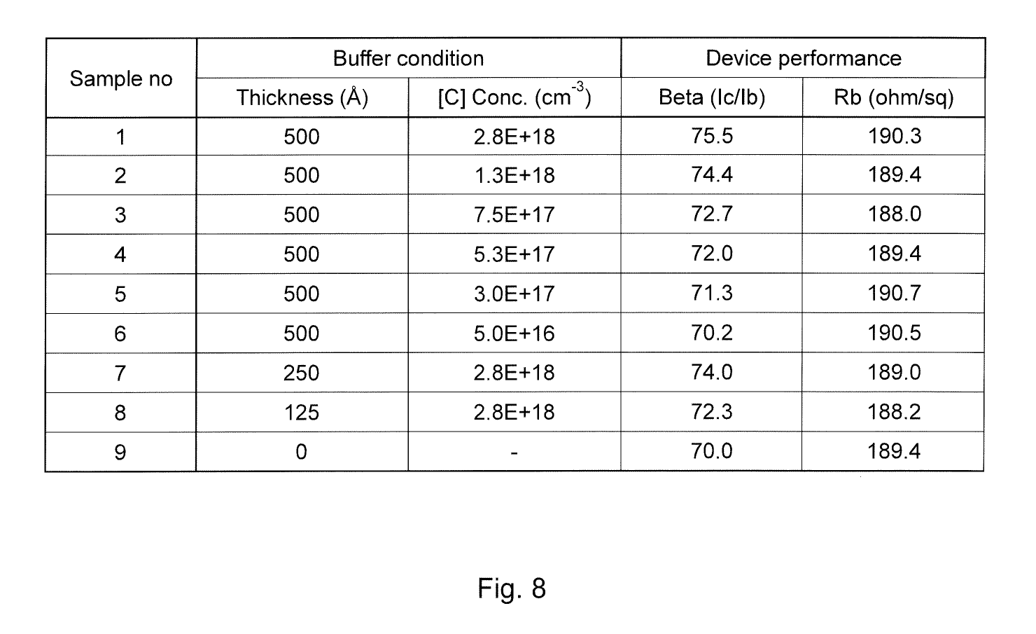

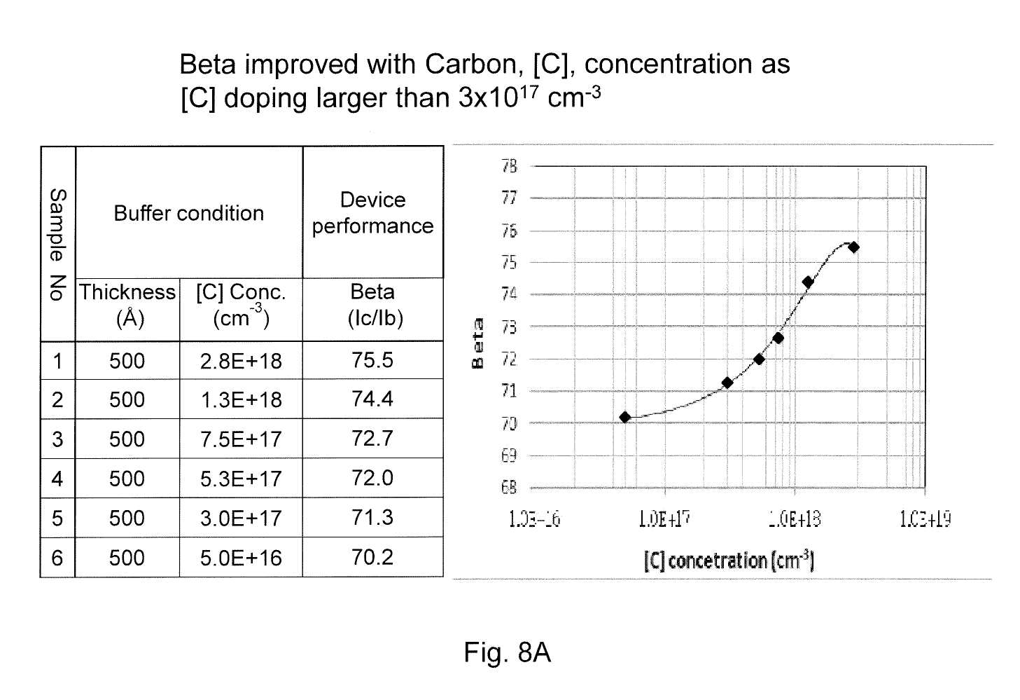

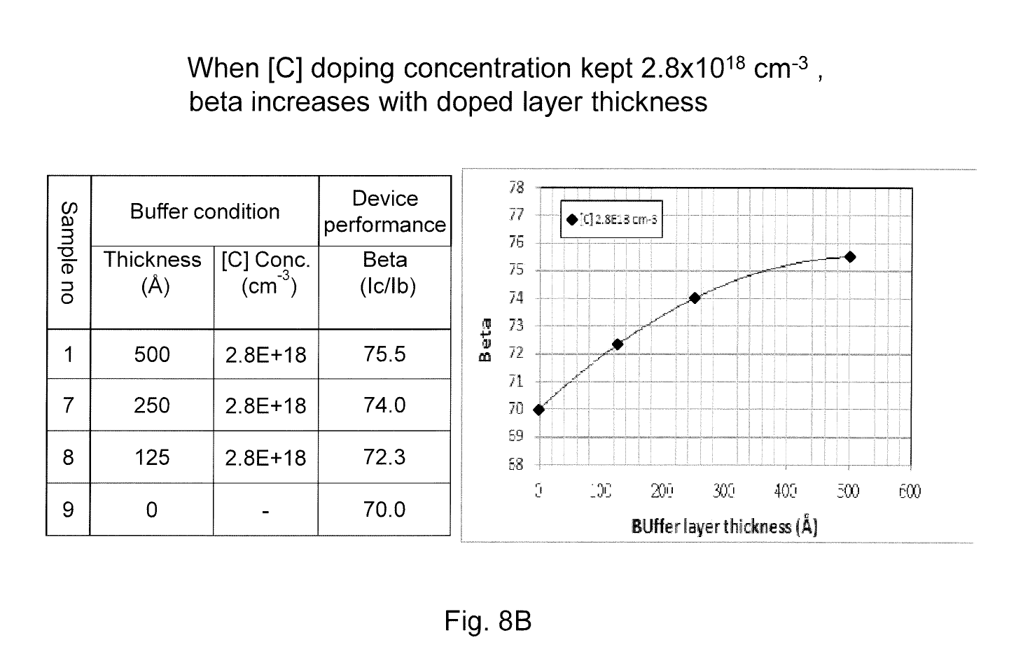

Please refer to FIG. 8-8B, shown the performance of the various embodiments of the present invention. Sample No. 1-5 are various embodiments of the present invention having the modulation-doped buffer structure 203 of FIG. 4A. The modulation-doped buffer structure 203 of Sample No. 1-5 comprises one doped layer 2031 having a thickness of 500 Å and doped with a dopant element carbon(C). The doping concentration of Sample No. 1-5 are at 2.8×10¹⁸ cm⁻³, 1.3×10¹⁸ cm⁻³, 7.5×10¹⁷ cm⁻³, 5.3×10¹⁷ cm⁻³ and 3.0×10¹⁷ cm⁻³ respectively. The modulation-doped buffer structure 203 of Sample No. 6 is a layer having a thickness of 500 Å and doped with a dopant element carbon(C) at doping concentration 5.0×10¹⁶ cm⁻³. Sample No. 7-8 are various embodiments of the present invention having the modulation-doped buffer structure 203 of FIG. 4A. The modulation-doped buffer structure 203 of Sample No. 7-8 comprises one doped layer 2031 having respectively a thickness of 250 Å and a thickness of 125 Å and doped with a dopant element carbon(C) at doping concentration 2.8×10¹⁸ cm⁻³. The HBT device of Sample No. 9 has no modulation-doped buffer structure 203.

Please refer to FIG. 8A which shows the performance diagram of Sample No. 1-6. The performance diagram shows the comparison of varying the doping concentration with the fixed thickness (500 Å). The result is very clear that as long as the doping concentration is increased, the current gain (beta) is improved while the base resistance (Rb) remains about 190 ohm/cm⁻². The current gain (beta) improvement is very obvious when the doping concentration is higher than 3.0×10¹⁷ cm⁻³.

Please refer to FIG. 8B which shows the performance diagram of Sample No. 1, 7 and 8. The performance diagram shows the comparison of varying the thickness with the fixed doping concentration (2.8×10¹⁸ cm⁻³). The result is very clear that as long as the thickness is increased, the current gain (beta) is improved while the base resistance (Rb) remains about 190 ohm/cm⁻². However when the thickness is higher than 3000 Å, there comes out the leakage problem. Hence, the thickness is at least 10 Å and better less than 3000 Å.

To sum up, the present invention can indeed get its anticipated object by incorporating a modulation-doped buffer structure to improve the current gain of an HBT. The on-state resistance of the device can be significantly decreased, while the current gain and the efficiency of the power amplifier can be enhanced remarkably. The present invention also provides fabrication processes for HBTs with improved device reliability.

Although the embodiments of the present invention have been described in detail, many modifications and variations may be made by those skilled in the art from the teachings disclosed hereinabove. Therefore, it should be understood that any modification and variation equivalent to the spirit of the present invention be regarded to fall into the scope defined by the appended claims.

What is claimed is:

1. A heterojunction bipolar transistor (HBT) with improved current gain, comprising:
a substrate;
a modulation-doped buffer structure formed on said substrate, wherein said modulation-doped buffer structure includes at least one doped layer having a thickness of at least 10 Å and less than 3000 Å and doped with a dopant element at doping concentration at least 3×10¹⁷ cm⁻³ and no greater than 2×10²⁰ cm⁻³, wherein said dopant element is selected from the group consisting of C, Zn, Mg, Be and S;
an n-type sub-collector layer formed on said modulation-doped buffer structure;
an n-type collector layer formed on said n-type sub-collector layer;
a p-type base layer formed on said n-type collector layer;
an n-type emitter layer formed on said p-type base layer;
a collector electrode formed at one end of said n-type sub-collector layer;
a base electrode formed at one end of said p-type base layer; and
an emitter electrode formed on said n-type emitter layer.

2. The HBT with improved current gain according to claim 1, wherein said modulation-doped buffer structure is formed of material selected from the group consisting of GaAs, AlGaAs, InGaP, InAlP, InGaAsP and AlGaInP.

3. The HBT with improved current gain according to claim 1, wherein said modulation-doped buffer structure further comprises at least one additional layer.

4. The HBT with improved current gain according to claim 3, wherein said modulation-doped buffer structure is formed by alternately stacking said at least one doped layer and said at least one additional layer.

5. The HBT with improved current gain according to claim 3, wherein each of said at least one additional layer is fully doped, partially doped or undoped.

6. The HBT with improved current gain according to claim 5, wherein the doping concentration is at least 3×10¹⁷ cm⁻³ and no greater than 2×10²⁰ cm⁻³ with doped a thickness less than 10 Å.

7. The HBT with improved current gain according to claim 5, wherein the doping concentration is less than 3×10¹⁷ cm⁻³ or greater than 2×10²⁰ cm⁻³.

8. The HBT with improved current gain according to claim 1, wherein said dopant element is C.

9. The HBT with improved current gain according to claim 1, wherein said dopant element is Zn.

10. The HBT with improved current gain according to claim 1, wherein said dopant element is Mg.

11. The HBT with improved current gain according to claim 1, wherein said dopant element is Be.

12. The HBT with improved current gain according to claim 1, wherein said dopant element is S.

13. The HBT with improved current gain according to claim 1, wherein said substrate is formed of GaAs.

14. The HBT with improved current gain according to claim 1, further comprising an n-type emitter cap layer between said n-type emitter layer and said emitter electrode.

15. The HBT with improved current gain according to claim 14, further comprising an n-type emitter contact layer between said n-type emitter cap layer and said emitter electrode.

16. The HBT with improved current gain according to claim 1, further comprising an n-type emitter contact layer between said n-type emitter layer and said emitter electrode.

17. The HBT with improved current gain according to claim 1, wherein said at least one doped layer has a thickness of at least 30 Å and less than 3000 Å and is doped with said dopant element at doping concentration at least 3×10¹⁷ cm⁻³ and no greater than 2×10²⁰ cm⁻³.

18. The HBT with improved current gain according to claim 1, wherein said at least one doped layer has a thickness of at least 50 Å and less than 3000 Å and is doped with said dopant element at doping concentration at least 3×10¹⁷ cm⁻³ and no greater than 2×10²⁰ cm⁻³.

19. The HBT with improved current gain according to claim 1, wherein said at least one doped layer has a thickness of at least 100 Å and less than 3000 Å and is doped with said dopant element at doping concentration at least 3×10¹⁷ cm⁻³ and no greater than 2×10²⁰ cm⁻³.

20. The HBT with improved current gain according to claim 1, wherein said at least one doped layer has a thickness of at least 200 Å and less than 3000 Å and is doped with said dopant element at doping concentration at least 3×10′⁷ cm⁻³ and no greater than 2×10²⁰ cm⁻³.
